(19) United States
(12) Patent Application Publication
(10) Pub. No.: US 2010/0097767 A1
(43) Pub. Date: Apr. 22, 2010

(54) Machine for passively removing heat generated by an electronic circuit board

(76) Inventors: John David Jude, Scottsdale, AZ (US); John Carl Bastian, Yorkville, IL (US)

Correspondence Address: John D. Jude, 6102 E. Redfield Rd, Scottsdale, AZ, 85254, US

(21) Appl. No.: 12/288,264

(22) Filed: Oct. 18, 2008

(51) Int. Cl. H05K 7/20

(52) U.S. Cl. 361/709

(57) ABSTRACT

A machine for passively removing heat generated by an electronic circuit board is disclosed. In a typical embodiment an electronic circuit board of any type or size is comprised of electronic components producing heat during operation. High thermal conductivity moldable pads applied to both sides of the electronic circuit board form a conductive pathway to transport heat away from electronic circuits and components. A two piece rigid heat sink having thin rigid conductive fins on its top base is coupled together forming a cavity into which the computer board/conductive pad assembly fits, thereby forming a second conductive pathway for heat transport away from board features. The thin rigid conductive fins collectively form yet a third conductive pathway for heat transport from the solid base of the two piece rigid heat sink. Exposure of the thin rigid conductive fins to cooler surrounding air provides convective transfer of heat from the fins to ambient air.

### CROSS REFERENCE TO RELATED APPLICATIONS

Not Applicable

### STATEMENT REGARDING FEDERALLY SPONSORED RESEARCH OR DEVELOPMENT

Not Applicable

### DESCRIPTION OF ATTACHED APPENDIX

Not Applicable

### BACKGROUND OF THE INVENTION

This invention relates generally to the field of electronics cooling technology and more specifically to a machine for passively removing heat from electronic circuit boards.

Over the past decade single board computing platforms have become much more powerful stemming from the construction and integration of advanced chipsets needed to operate modern software applications. Electronic circuit boards have also become smaller, in large part due to high energy density components and advanced circuitry that allow very compact and lightweight electronic devices to perform a myriad of complex functions once reserved for large non-portable computer systems. The integration of high energy density components onto electronic circuit boards has created the technical challenge of how best to remove significant heat generated at the component and board levels without consuming additional energy and compromising the compact and lightweight nature of the systems into which they are incorporated. Typically, computer systems constructed from multiple electronic circuit boards are housed inside of a single enclosure similar to those used for a desktop PC or rackmount computer system. These systems generally have few space claim or power budget restrictions and are usually exposed to a relatively clean and dry environment where a low to moderate ambient temperature enables one or more mechanical fans to sufficiently circulate ambient air throughout the enclosure to keep board level components cool. Some computer systems using multiple circuit boards do however have restrictions on both space claim and power budget and operate in harsh environments containing airborne particulates of dirt, dust, moisture, liquids, extreme temperatures and even flammable vapors. In these applications computer enclosures must be hermetically sealed to prevent exposure of electronic components to such materials that can significantly reduce their useful operating life. Without the integration of some form of active thermal management system such as a refrigeration circuit, thermoelectric coolers or heat pipes to remove heat, hermetically sealed computer enclosures overheat causing computer failure and component destruction. Ideally, a passive thermal management solution using only conduction and free flow convection heat transport is needed to eliminate the utilization of additional electrical energy to power cooling devices and lessen the additional space required to integrate them into a sealed computer enclosure. The invention disclosed eliminates the need for electrically powered cooling devices, a large hermetically sealed enclosure and unreliable or fragile mechanical systems. The invention separates electronic circuit boards and encases each in a finned heat sink module that relies upon conduction of heat from board level components to finned surfaces having a large exposed surface area from which heat is transferred to cooler ambient air via natural or forced convection. Separation of the circuit boards into individual passively cooled modules has several advantages over current active cooling technology including elimination of the effect of proximity heating of low power circuit boards by adjacent high power circuit boards within the same enclosed environment, elimination of additional electrical power requirements specifically for component cooling, increasing the degree of board level component ruggedization against shock and vibration and providing a reliable hermetic seal against dust, dirt and moisture. No fans, pumps, liquids or compressors are required and therefore all moving parts are eliminated in the overall design of the invention providing “any orientation” operation, energy efficiency and an extremely rugged and reliable electronics unit. The invention disclosed can be fabricated and implemented for a multitude of electronic platforms and sizes including, but not limited to VME, VME 64x, VPX, VXS, PCI, PCIx, cPCI, mTCA, aTCA, uTCA, PC 104, ATX, uATX, Mini ATX, PICMG 2.16, PICMG 2.17, PICMG 2.18, VITA 1.7, VITA 31.1, VITA 46 and in heights including but not limited to 1 U through 15 U.

Although finned heat sinks have been extensively applied to cool individual heat generating electronic components particularly processor, power, graphics and memory circuits, we have found no prior art in which a finned heat sink assembly has been used in combination with other conductive materials and fabricated in such a manner as to fully encase an entire printed circuit board or electronic circuit board and thereby conductively and convectively remove heat from it and its components. Typically the combination of thermally conductive pads, pastes or polymers and highly conductive metal finned heat sinks are integrated at the component level of a circuit board and are designed only to transport heat from a localized hot spot. These devices are often subjected to a forced flow of air or liquid from a heat exchange system, refrigeration system, thermoelectric coolers or a spray cooling system installed on or within the hermetically sealed enclosure. In some cases these heat sinks contain channels or voids in their base through which a chilled working liquid is pumped to increase the rate at which heat transfer occurs. Heat pipes are an alternative form of heat sink in which a liquid-vapor interface forms at the point source of heat generation. A heat pipe efficiently absorbs heat by using it to vaporize a liquid working fluid. Once in its vapor state the fluid is transported along with latent heat of vaporization to a chilled surface where the vapor is condensed back into a liquid and returned to the localized source of heat generation. Heat pipes are also generally used as hot spot cooling devices and have not been utilized for cooling electronics at the board level. Currently no other passive or active electronics thermal management technology of record segregates individual circuit boards from one another and encases each board in its own heat sink module such that proximity or cumulative heating is eliminated. A single sealed enclosure is not required and only conduction and natural convection accounts for heat transport from all board surfaces, circuits and components.

Unlike prior technology the invention disclosed requires no electrical power to transport relatively large amounts of heat from multiple electronic circuit boards because it does not seal all boards within a single enclosure from which all accumulated heat must be removed. The current invention separates all circuit boards and seals each within its own finned heat sink enclosure preventing cross heating of adjacent boards and reducing the amount of required heat transfer to just that generated by a single board. Refrigeration devices, liquid spray cooling systems and heat pipes are each sensitive to the physical orientation under which they operate and lose significant efficiency, cooling capability and reliability when operated at any orientation beyond the horizontal for any length of time. The disclosed invention operates under any static and dynamic orientation without loss of efficiency or reliability. Refrigeration systems, thermoelectric coolers and spray cooling devices attached to component heat sinks require between one third and three times as much energy to operate as they transport in the form of heat, whereas the present invention requires no electical power. Refrigeration systems, spray cooling devices and heat pipes require the use of moving mechanical parts, liquids or both, while the present invention requires no working liquids and has no moving mechanical parts that can fail.

### BRIEF SUMMARY OF THE INVENTION

The primary object of the invention is to provide an electronic circuit board cooling device that requires no active cooling features such as refrigerators, evaporators, condensers, heat exchangers, thermoelectric coolers, pumps, fans or liquids.

Another object of the invention is to provide an electronic circuit board cooling device that enables efficient thermal management at the single board level rather than the inefficient thermal management of multiple boards housed within a single rigid enclosure.

Another object of the invention is to provide an electronic circuit board cooling device that is compact and lightweight.

A further object of the invention is to provide an electronic circuit board cooling device that can be utilized to passively cool any type of circuit board including but not limited to, micro processors, CPUs, graphics, communication, data collection, networking, input/output, modem, memory, power supply and power conditioning devices among others.

Yet another object of the invention is to provide an electronic circuit board cooling device that is composed of commonly available materials and is easily manufactured.

Still yet another object of the invention is to provide an electronic circuit board cooling device that uses only conduction and convection to remove heat generated by electrically powered board components and assemblies.

Another object of the invention is to provide an electronic circuit board cooling device that eliminates the inefficient accumulation of heat found in single rigid sealed enclosures containing multiple circuit boards and eliminates proximity heating of low power boards located adjacent to high power boards.

Another object of the invention is to provide an electronic circuit board cooling device that enhances the shock and vibration stability of electronic circuit board components by potting them into place using moldable and rigid outer layers.

Another object of the invention is to provide circuit board swapping or replacement without opening a main enclosure.

Another object of the invention is to provide a cooling device for storage devices that include read only or read/writeable devices including hard disks, solid state drives, flash drives, optical drives including CD, DVD, Blu-Ray, floppy drives and tape drives.

A further object of the invention is to provide an electronic circuit board cooling device that is scalable for cooling boards of all types and sizes including but not limited to: VME, VME 64x, VPX, VXS, PCI, PCIx, cPCI, mTCA, aTCA, UTCA, PC 104, ATX, uATX, MiniATX, PICMG 2.16, PICMG 2.17, PICMG 2.18, VITA 1.7, VITA 31.1, VITA 46 and in heights including 1 U through 15 U.

Still yet another object of the invention is to provide an electronic circuit board cooling device that is easily optimized relative to size and weight for cooling individual boards with variable thermal loads.

Another object of the invention is to provide an electronic circuit board cooling device that fully seals to protect an individual board and its components from exposure to dirt, dust, fungus, humidity, moisture, liquids and other environmental contaminants and protects the board and all components from exposure to moisture when submersed in fresh or salt water.

Other objects and advantages of the present invention will become apparent from the following descriptions, taken in connection with the accompanying drawings, wherein, by way of illustration and example, an embodiment of the present invention is disclosed.

In accordance with a preferred embodiment of the invention, there is disclosed a machine for passively removing heat generated by an electronic circuit board comprising: an electronic circuit board having a plurality of circuits and electronic components that when supplied with electrical power produce heat, high thermal conductivity moldable pads in thermal contact with and adherent to both sides of the electronic circuit board that form conductive pathways for the transport of heat away from electronic circuits and components, a two piece rigid heat sink that when joined together forms a cavity, the inside surfaces of which are in thermal contact with and adherent to the top surfaces of the highly conductive moldable pads, a two piece rigid heat sink that surrounds and encloses the single board computer board, electronic circuit board heat spreaders and highly conductive moldable pads by means of fasteners that couple together each side of the two piece rigid heat sink forming a conductive pathway for the transport of heat away from the conductive pads, a plurality of thin rigid conductive fins coupled to the top base of the two piece rigid heat sink collectively forming a convective pathway for the transport of heat from the top base of the two piece rigid heat sink to surrounding ambient air.

### BRIEF DESCRIPTION OF THE DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1A is an exploded view of the invention showing multiple individual single board computer boards encased in two piece finned heat sink cooling modules and a typical power buss and I/O backplane into which they would be connected to form an entire computer system. This figure illustrates a complete computer system constructed using the present invention.

FIG. 1B is a plan view of the invention illustrating multiple individual single board computer boards encased in two piece finned heat sink cooling modules and attached to a power buss and I/O backplane along with finned cooling modules that house the computer system power supplies. This plan view clarifies the assembly of the complete computer system constructed using the present invention.

FIG. 2A is an exploded view of the invention showing each individual element that comprises the construction of the electronic circuit board cooling module.

FIG. 2B is a cross sectional view of the invention illustrating the placement of each individual element within a fully assembled electronic circuit board cooling module.

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

The present invention contemplates a novel electronic circuit board cooling device that is fabricated using an electronic circuit board of any type or size as the central layer of a series of layers of metal and non-metal conductive materials that readily and rapidly distribute heat through conduction from localized heat sources to large conductive surface areas. The present invention also provides numerous benefits over prior electronic circuit board and component cooling technology, those will be noted.

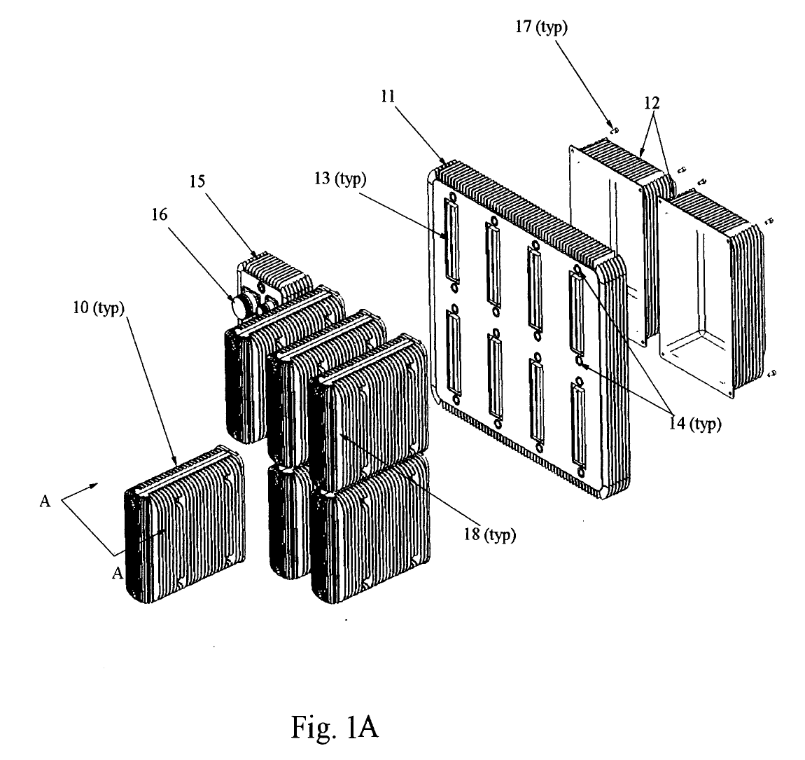

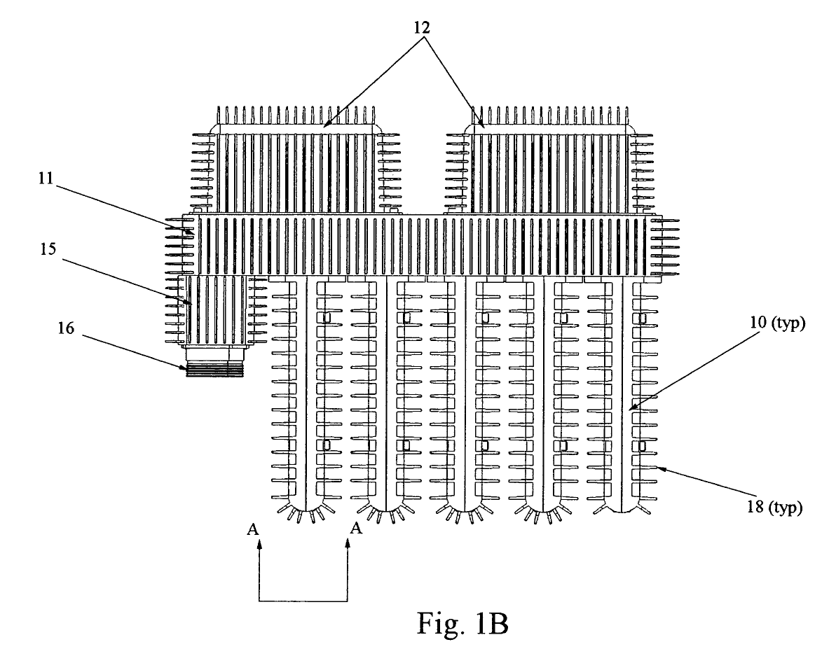

Turning first to FIG. 1A there is presented an illustrative embodiment of the primary elements that comprise the present invention in exploded view. This figure is presented first to teach those familiar in the art of the overall result of applying the current invention, details of which will be provided next. The passively cooled modular board 10 is a member of a modular board cluster 18 comprising all necessary electronic circuit boards to contruct a complete working computer system. Passively cooled modular board 10 in typical fashion is comprised of an electronic circuit board, thermally conductive materials and a two piece rigid heat sink and is coupled to a passively cooled power buss backplane 11 by means of power buss back plane couplings 14 to a power buss backplane connector 13. Additional components of this preferred embodiment of the present invention include a passively cooled input/output module 15 comprised of input/output connectors 16 also coupled to the passively cooled power buss backplane 11 by means of power buss back plane couplings 14 to a power buss backplane connector 13. In certain embodiments of the present invention, passively cooled power supply module(s) 12 may be coupled to the passively cooled power buss back plane 11 by means of screw fasteners or other couplings. FIG. 1A presents that the primary departure from typical computer systems composed of multiple electronic circuit boards that makes the current invention non-obvious is the absence of a single computer enclosure into which all components are sealed. One benefit of seating computer boards as a passively cooled modular board 10 is that the heat generated by other computer boards within the modular board cluster 18 do not cause proximity heating of adjacent boards. Additionally, the exposure of a significant surface area for convective cooling provided by each passively cooled modular board 10, the passively cooled input/output module 15 and the passively cooled power buss back plane 11 in an open ambient environment eliminates the need for inclusion of active cooling elements such as refrigeration systems, liquids or fans.

Turning now to FIG. 1B there is a plan view illustrative embodiment of the primary elements that comprise the present invention. A typical passively cooled modular board 10 is shown as part of a passively cooled board cluster 18, herein coupled to passively cooled back plane buss 11. Also attached to the passively cooled back plane buss 11 are the passively cooled input/output module 15 and passively cooled power supply module(s) 12. FIG. 1B illustrates among other features the densely finned heat sink enclosures that serve to encase each individual element of the current invention an owes to its propensity to generate considerable free flow convection air cooling over and between each protruding fin. An obvious advantage of the design of the present invention is that each individual passively cooled modular board 10 can be removed for replacement or repair without the need to open and single hermetically sealed enclosure with concern for reestablishing a proper seal against environmental contamination.

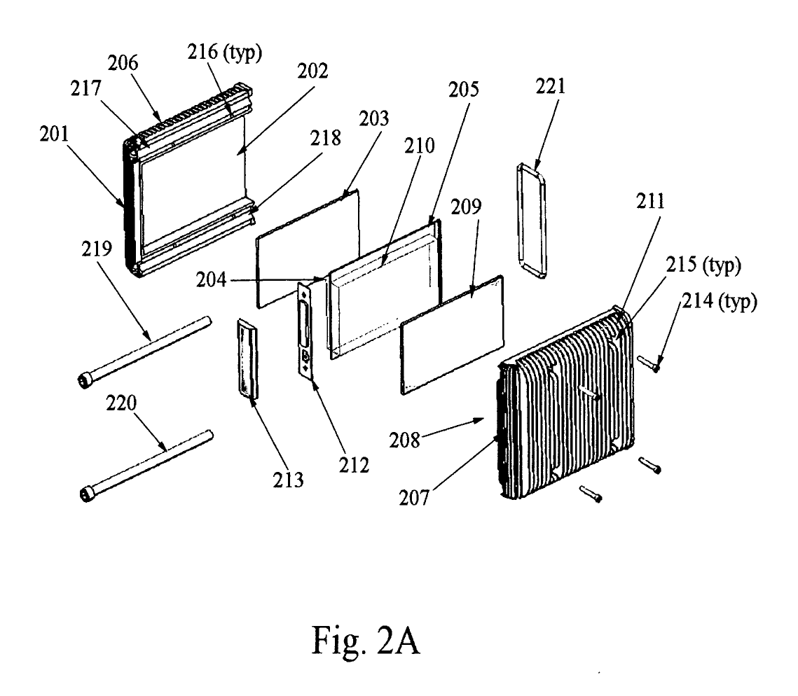

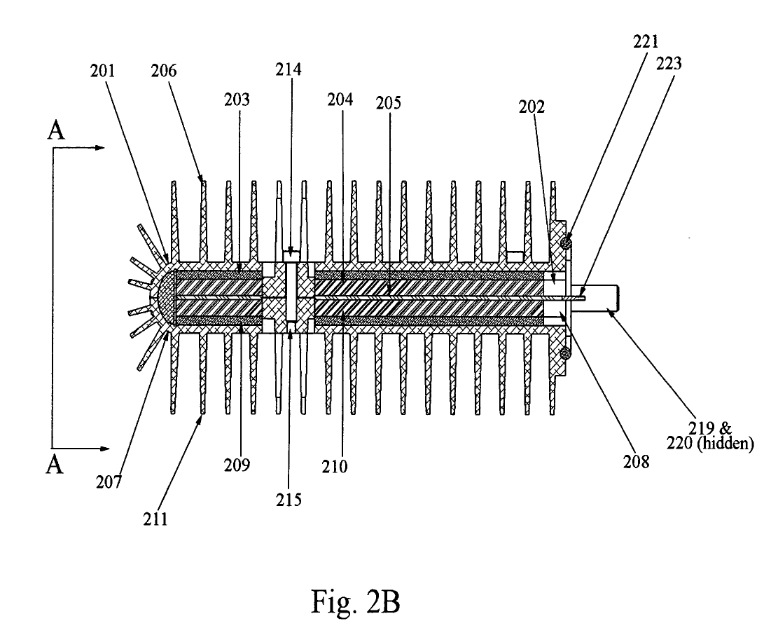

FIG. 2A provides an exploded view of the primary elements comprising the passively cooled modular card 10 of FIGS. 1A and 1B which is the principal focus of the current invention. Beginning with the electronic circuit board 205, that may be of any type or size, there is attached an electronic circuit board bracket 212 generally of aluminum or other suitable metals or plastics that provides lateral strength to the board and may contain input and output connections. A right side heat spreader plate 210 composed of highly conductive metal from the group copper, aluminum, titanium, silver and alloys thereof or carbon in any of its solid forms is in direct contact and thermal communication with one or more heat generating components of electronic circuit board 205. In direct contact and thermal communication with right heat spreader plate 210 is right side highly conductive moldable pad 209 of polymer, composite or other appropriate conformal material that can be sprayed, painted, machined molded or manually molded in various thickness so as to provide a level right face for beneficial direct contact with other conductive elements. A second left heat spreader plate 204 also comprised of highly conductive metal from the group copper, aluminum, titanium, silver and alloys thereof or carbon in any of its solid forms is, in the preferred embodiment, in direct contact and thermal communication to the left side of electronic circuit board 205 to distribute heat from circuits and components thereon located. In some embodiments of the present invention, left heat spreader plate 204 may be excluded as unnecessary for adequate heat distribution and may be replaced with left side highly conductive moldable pad 203. Left side highly conductive moldable pad 203 is in direct contact and thermal communication with either left heat spreader plate 204 or left face of electronic circuit board 205 and is of polymer, composite or other appropriate material that can be sprayed, painted, machined molded or manually molded in various thickness so as to provide a level left face for beneficial direct contact with other conductive elements. Front side highly conductive moldable pad 213 in direct contact and thermal communication with electronic circuit board bracket 212 is of polymer, composite or other appropriate material that can be sprayed, painted, machined molded or manually molded in various thickness so as to provide a level right face for beneficial direct contact with other conductive elements. Front side highly conductive moldable pad 213 may be eliminated as an element of the present invention in certain embodiments where single board computer bracket 212 contains input and out put connections that must be readily accessed. Left side heat sink 201 comprised of left side fins 206 and left side cavity 202 together with right side heat sink 207 comprised of right side fins 211 and right side cavity 208 are ultimately coupled to form the fully assembled two piece rigid heat sink referenced earlier in this application. In alternate embodiments of the current invention the two piece rigid heat sink may, when beneficial to support particular electronic circuit board architecture, be fabricated of one or of multiple parts or pieces while maintaining the general form and function herein described. Left side heat sink 201 and its components and right side heat sink 207 and its components are of highly conductive metal from the group copper, aluminum, titanium, silver and alloys thereof or carbon in any of its solid forms. The surface of right side cavity 208 is in direct contact and thermal communication with the top surface of right side highly conductive moldable pad 209 and thereby form a complete conductive pathway for heat transfer from the right side of electronic circuit board 205. The surface of left side cavity 202 is in direct contact and thermal communication with the top surface of left side highly conductive moldable pad 203 and thereby form a complete conductive pathway for heat transfer from the left side of electronic circuit board 205. Left side heat sink 201 and right side heat sink 207 are coupled to compress all inner layers of the present invention thereby ensuring contact and thermal communication of all material faces by means of a plurality of fasteners 214 passed through a plurality of typical right side openings 215 penetrating right side heat sink 207 that are aligned with a plurality of typical left side openings 216 penetrating left side heat sink 201. Channels 217 and 218 that run the length of the top and bottom sides of left side heat sink 201 and right side heat sink 207 accept fastener rods 219 and 220 respectively, which provide a means to couple the entire assembly to any suitable back plane power buss connection or back plane input/output connection. O-ring 221 of plastic, rubber, polymer or other acceptably elastic material is seated at the rear of the two piece rigid heat sink formed by left side heat sink 201 and right side heat sink 207 and provides a seal between the completed assembly and the back plane to which it is coupled.

FIG. 2B provides a cross section view of the preferred embodiment of the present invention indicated by Section A-A of FIGS. 1A and 1B. Heat is generated by circuitry and electronic components of electronic circuit board 205 when coupled through electronic circuit board buss connector 223 to a back plane power buss by means of fastener rods 219 and 220 during its operation. As heat is generated by both right side and left side circuitry and components of electronic circuit board 205, that heat is transferred by means of conduction to right side heat spreader plate 210 and left side heat spreader plate 204 each of which are of high conductive rigid materials having a mechanical structure that enables heat conducting into them to be rapidly and evenly distributed throughout their cross section and surface area. This even distribution of heat from high flux point sources on electronic circuit board 205 is critical to the successful passive operation of the present invention in that heat distribution over an expansive area prevents point source accumulation and component overheating. Previous art does not take full advantage of heat spreader plate technology in that previous art heat spreaders are generally applied over a much smaller area such as atop processor chips, to the exclusion of other surface features which may produce smaller amounts of heat. Previous art heat spreaders typically do not extend the entire width and length of an electronic circuit board as in the present invention. In the preferred embodiment, heat transferred to the right side heat spreader plate 210 and left side heat spreader plate 204 is transferred by means of conduction through a thickness of right side highly conductive moldable pad 209 and left side highly conductive moldable pad 203 respectively. Both right side highly conductive moldable pad 209 and left side highly conductive moldable pad 203 may be of the same material formulation or of different material formulations depending on the conductivity required for each side of a specific electronic circuit board. Similarly they may be of the same thickness or of different thicknesses to best accommodate differing heat flux generated by right side and left side components. Right side highly conductive moldable pad 209 and left side highly conductive moldable pad 203 each also serve as a medium to compensate for uneven surface features on right side heat spreader plate 210 and left side heat spreader plate 204 respectively, thereby ensuring thorough contact and thermal communication between the heat spreader plates and the faces of left side heat sink cavity 202 and right side heat sink cavity 208. The surface contact between right side highly conductive moldable pad 209 and the face of right side heat sink cavity 208 as well as that between left side highly conductive moldable pad 203 and the face of left side heat sink cavity 202 results in the transfer of heat through conduction into the bases of right side heat sink 207 and left side heat sink 201 respectively. The temperature gradient between the base of right side heat sink 207 and right side heat sink fins 211 causes rapid conduction of heat into the fins which are exposed to cooler ambient air. Similarly the temperature gradient between the base of left side heat sink 201 and left side heat sink fins 206 causes rapid conduction of heat into these fins which are exposed to cooler ambient air. Previous art does not pursue or illustrate a heat sink encapsulating and entire board and as such, previous heat sink art has not benefited from the significant enhancement of heat transfer rate that can be accomplished with such large surface area that is provided in the present invention. In the preferred embodiment of the current invention, an established temperature gradient between the right side heat sink fins 211 and cooler surrounding ambient air and between the left side heat sink fins 206 and cooler surrounding ambient air creates a natural flow of air across the finned surfaces owing to that temperature gradient that convectively removes heat from the finned surfaces to establish thermal equilibrium between them and the ambient air. Because the temperature difference between the finned surfaces and ambient can be relatively small, on the order of only 20 F, the total area of the finned surfaces is made large so that a low rate of heat transfer owing to a small temperature gradient can be overcome by the large cumulative heat flux generated over a large surface area. It is however possible given the flexible design of the present invention to greatly reduce the surface area and subsequent size and weight of the fins if the ambient air temperature can be easily held within a narrow and predictable range. Owing to its ability to remove large amounts of heat from an electronic circuit board without the need for electrically powered components, without moving parts or liquids, in addition to the beneficial enhancement of shock and vibration stability resulting from the potting of board components by conductive inner layers and the ability of the preferred embodiment to operate in any physical orientation, it is clear that the present invention represents a non-obvious and novel electronic circuit board cooling device.

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

What is claimed is:

1. A machine for passively removing heat generated by an electronic circuit board comprising:
an electronic circuit board having a plurality of circuits and electronic components that when supplied with electrical power to function also produce heat;
high thermal conductivity moldable pads in thermal contact with and adherent to both sides of the electronic circuit board or electronic circuit board heat spreaders that form conductive pathways for the transport of heat away from electronic circuits and components;
a two piece rigid heat sink, the parts of which when coupled together form a cavity with inside surfaces that are in contact with and adherent to the top surfaces of the highly conductive moldable pads;
a two piece rigid heat sink that surrounds and encases the electronic circuit board, electronic circuit board heat spreaders and highly conductive moldable pads by means of fasteners that couple together each side of the two piece rigid heat sink to form a conductive pathway for the transport of heat away from the conductive pads; and
a plurality of thin, rigid conductive fins coupled to each top base of the two piece rigid heat sink thereby collectively forming a pathway for the transport of heat from the solid base of the two piece rigid heat sink to surrounding ambient air by means of natural or forced convection.

2. A machine for passively removing heat generated by an electronic circuit board as claimed in claim 1 wherein said electronic circuit board may be of any architecture, type and size and may be comprised of any combination of electronic components such as integrated circuits, electronic processing devices, graphics processing devices, memory devices, diodes, resistors, capacitors and others.

3. A machine for passively removing heat generated by an electronic circuit board as claimed in claim 1 wherein said electronic circuit board may be comprised of factory supplied or custom manufactured heat spreaders for the transfer and distribution of heat away from any combination of said electronic circuit board circuits or electronic components

4. A machine for passively removing heat generated by an electronic circuit board as claimed in claim 3 wherein said factory supplied or custom manufactured heat spreaders are of highly conductive materials from the group copper and its alloys, aluminum and its alloys, silver and its alloys, titanium and its alloys, tin and its alloys or carbon in any of its solid forms

5. A machine for passively removing heat generated by an electronic circuit board as claimed in claim 1 wherein said high thermal conductivity moldable pads comprises a thermally conductive layer in thermal contact with all heat generating features of both sides of said electronic circuit board; wherein the heat generating features on both sides of said electronic circuit board may be factory supplied or custom manufactured heat spreaders that themselves are in thermal contact with component level heat generating features

6. A machine for passively removing heat generated by an electronic circuit board as claimed in claim 5 wherein said high thermal conductivity moldable pads are comprised of any combination of high conductivity material that can be in thermal contact with said electronic circuit board heat generating features and provide a conductive thermal pathway from those features while providing a level top surface for ensuring thermal contact with additional conductive materials

7. A machine for passively removing heat generated by an electronic circuit board as claimed in claim 1 wherein said two piece rigid heat sink comprises a thermally conductive bottom base in thermal contact with said high thermal conductivity moldable pads, themselves in thermal contact with said electronic circuit board heat generating features as described in claim 5, and further providing a conductive thermal pathway for heat from said high thermal conductivity moldable pads

8. A machine for passively removing heat generated by an electronic circuit board as claimed in claim 1 wherein said two piece rigid heat sink is comprised of a conductive top base coupled to a plurality of thin rigid conductive fins that provide a conductive thermal pathway for heat from said two piece rigid heat sink.

9. A machine for passively removing heat generated by an electronic circuit board as claimed in claim 8 wherein said two piece rigid heat sink and said conductive thin rigid conductive fins are of identical or combinations of materials selected from the group consisting of copper and its alloys and oxides, aluminum and its alloys and oxides, silver and its alloys and oxides, titanium and its alloys and oxides and carbon in all of its solid forms.

10. A machine for passively removing heat generated by an electronic circuit board as claimed in claim 9 wherein said thin rigid conductive fins collectively comprise a large surface area that when heated through conduction generates free-flow convective heat transfer to the surrounding lower temperature ambient air

11. A machine for passively removing heat generated by an electronic circuit board as claimed in claim 1 wherein said plurality of thin rigid conductive fins coupled to each top base of said two piece rigid heat sink can be varied in thickness, height, number and spatial orientation so as to transfer heat loads specific to various electronic circuit boards in a package having the least size and weight

12. A machine for passively removing heat generated by an electronic circuit board as claimed in claim 1 wherein said high thermal conductivity moldable pads in thermal contact with and adherent to both sides of the electronic circuit board or electronic circuit board heat spreaders and forming conductive pathways for the transport of heat away from electronic circuits and components of said electronic circuit board can be applied through spraying, painting, casting, machine molding or manual molding of materials onto said electronic circuit board features and surfaces

13. A machine for passively removing heat generated by an electronic circuit board as claimed in claim 1 wherein said two piece rigid heat sink comprises extruding, casting or machine milling of said two piece rigid heat sink construction materials so as to form an enclosure cavity specifically sized for any of various architectures, types or sizes of said electronic circuit boards

14. A machine for passively removing heat generated by an electronic circuit board as claimed in claim 1 wherein said plurality of thin rigid conductive fins are coupled to the top base of said two piece rigid heat sink by means of fasteners, adhesives, welds, soldering, or through the single piece extrusion, casting or machine milling of construction materials to form said plurality of thin conductive fins and said two piece rigid heat sink simultaneously.
